(19) United States
(12) Patent Application Publication
(10) Pub. No.: US 2026/0238200 A1
(43) Pub. Date: Aug. 13, 2026

(54) DRIVING METHOD OF DATA DRIVING DEVICE AND THE DATA DRIVING DEVICE

(71) Applicant: LX Semicon Co., Ltd., Daejeon (KR)

(72) Inventors: Chan Ho SHIN, Daejeon (KR); Jin Won CHOI, Daejeon (KR)

(73) Assignee: LX Semicon Co., Ltd., Daejeon (KR)

(21) Appl. No.: 19/534,017

(22) Filed: Feb. 9, 2026

(30) Foreign Application Priority Data
Feb. 10, 2025 (KR) 10-2025-0016643

(51) Int. Cl. H03K 5/135; G09G 3/20; G09G 3/3275; G09G 3/36; H03K 5/00

(52) U.S. Cl. CPC H03K 5/135; G09G 3/2007; G09G 3/2096; G09G 3/3275; G09G 3/3688; G09G 2320/0673; H03K 2005/00078

(57) ABSTRACT

A driving method of a data driving device and the data driving device are disclosed. The driving method includes receiving a data signal and a first clock signal from a timing controller, generating a second clock signal having a phase difference of 180° based on the received first clock signal, and transmitting first data, which is data of odd-numbered bits of the data signal, to a data register based on the first clock signal, and transmitting second data, which is data of even-numbered bits of the data signal, to the data register based on the second clock signal.

This application claims the benefit of Korean Patent Application No. 10-2025-0016643, filed on Feb. 10, 2025, which is hereby incorporated by reference as if fully set forth herein.

### BACKGROUND OF THE DISCLOSURE

### Field of the Disclosure

The present disclosure relates to a driving method of a data driving device and to the data driving device.

### Discussion of the Related Art

In high-speed data transmission environments, timing synchronization between a clock signal and a data signal is an important technical challenge. When the timing margin between the clock signal and the data signal is insufficient, loss of the data signal, signal distortion, or abnormal system operation may occur. Such problems may be particularly pronounced in high-frequency environments.

In conventional systems, data is processed using an architecture that mixes a clock signal (CLK) and an inverted-phase clock signal (CLKB). In this method, however, there may be a limit on operating frequency due to an insufficient timing margin between the CLK and the CLKB. In particular, stability may be degraded in high-speed data transmission environments. It may also be impossible to ensure stable operation in high-frequency environments. Furthermore, there may be constraints in scalability of system design.

In particular, these limitations have emerged as a major technical challenge in modern electronic devices and communication systems in which data transmission rates continue to increase and high-performance data processing is required.

### SUMMARY OF THE DISCLOSURE

Accordingly, the present disclosure is directed to a driving method of a data driving device and to the data driving device that substantially obviate one or more problems due to limitations and disadvantages of the related art.

The present disclosure can solve a problem in which a limit on operating frequency arises due to an insufficient timing margin between a clock signal (CLK) and an inverted-phase clock signal (CLKB) during data processing and a problem in which system stability is degraded in high-speed data transmission environments.

Aspects of the present disclosure are not limited to the above-described aspect, and other aspects of the present disclosure not yet described will be more clearly understood by those skilled in the art from the following description.

In an aspect of the present disclosure, a driving method of a data driving device includes receiving a data signal and a first clock signal from a timing controller, generating a second clock signal having a phase difference of 180° based on the received first clock signal, and transmitting first data, which is data of odd-numbered bits of the data signal, to a data register based on the first clock signal, and transmitting second data, which is data of even-numbered bits of the data signal, to the data register based on the second clock signal.

In the driving method according to at least one embodiment of the present disclosure, the transmitting the first data to the data register based on the first clock signal may include generating a third clock signal having a period corresponding to two times a period of the first clock signal, and generating a fifth clock signal delayed from the third clock signal by a 1-CLK time, and the 1-CLK time may be based on the first clock signal.

In the driving method according to at least one embodiment of the present disclosure, the transmitting the first data to the data register based on the first clock signal may further include sampling the first data at rising edges of the third clock signal and the fifth clock signal to generate first parallel data.

In the driving method according to at least one embodiment of the present disclosure, the transmitting the first data to the data register based on the first clock signal may further include generating a seventh clock signal having a period corresponding to four times the period of the first clock signal and delayed from the first clock signal by the 1-CLK time, and generating a ninth clock signal delayed from the seventh clock signal by the 1-CLK time.

In the driving method according to at least one embodiment of the present disclosure, the transmitting the first data to the data register based on the first clock signal may further include sampling the first parallel data at rising edges of the seventh clock signal and the ninth clock signal to generate third parallel data, and transmitting the third parallel data to the data register.

In the driving method according to at least one embodiment of the present disclosure, the transmitting the second data to the data register based on the second clock signal may include generating a fourth clock signal having a period corresponding to two times a period of the second clock signal, and generating a sixth clock signal delayed from the fourth clock signal by a 1-CLK time, and the 1-CLK time may be based on the first clock signal.

In the driving method according to at least one embodiment of the present disclosure, the transmitting the second data to the data register based on the second clock signal may further include sampling the second data at rising edges of the fourth clock signal and the sixth clock signal to generate second parallel data.

In the driving method according to at least one embodiment of the present disclosure, the transmitting the second data to the data register based on the second clock signal may further include generating an eighth clock signal having a period corresponding to four times the period of the second clock signal and delayed from the second clock signal by the 1-CLK time, and generating a tenth clock signal delayed from the eighth clock signal by the 1-CLK time.

In the driving method according to at least one embodiment of the present disclosure, the transmitting the second data to the data register based on the second clock signal may further include sampling the second parallel data at rising edges of the eighth clock signal and the tenth clock signal to generate fourth parallel data, and transmitting the fourth parallel data to the data register.

In another aspect of the present disclosure, a data driving device includes a receiver configured to receive a data signal and a first clock signal from a timing controller, a first clock generator configured to generate a second clock signal having a phase difference of 180° based on the received first clock signal, and a serial-to-parallel converter configured to transmit first data, which is data of odd-numbered bits of the data signal, to a data register based on the first clock signal and to transmit second data, which is data of even-numbered bits of the data signal, to the data register based on the second clock signal.

In an embodiment of the present disclosure, the first clock generator may be configured to generate a third clock signal having a period corresponding to two times a period of the first clock signal, and generate a fifth clock signal delayed from the third clock signal by a 1-CLK time, and the 1-CLK time may be based on the first clock signal.

In an embodiment of the present disclosure, the first clock generator may be configured to generate a fourth clock signal having a period corresponding to two times a period of the second clock signal, and generate a sixth clock signal delayed from the fourth clock signal by a 1-CLK time.

### BRIEF DESCRIPTION OF THE DRAWINGS

The accompanying drawings, which are included to provide a further understanding of the disclosure and are incorporated in and constitute a part of this application, illustrate embodiments of the disclosure and along with the description serve to explain the principle of the disclosure. In the drawings:

FIG. 1 is a diagram illustrating a configuration of a display device according to an embodiment of the present disclosure;

FIG. 2 is a diagram of a configuration of the data driving device according to an embodiment of the present disclosure;

FIG. 3 is a diagram illustrating operation of a serial-to-parallel converter and a second clock generator according to an embodiment of the present disclosure;

FIG. 4 is a diagram of clock signals and data sampling timing in the serial-to-parallel converter in first data transmission step according to an embodiment of the present disclosure; and

FIG. 5 is a diagram of clock signals and data sampling timing in the serial-to-parallel converter in second data transmission step according to an embodiment of the present disclosure.

### DETAILED DESCRIPTION OF THE DISCLOSURE

The present disclosure may be modified in various ways and provide various embodiments. Accordingly, the present disclosure will be described below through a detailed description of specific embodiments illustrated in the accompanying drawings. However, the detailed description is not intended to limit the present disclosure to the specific embodiments, and it should be understood that the present disclosure includes all changes, equivalents, or substitutions within the spirit and scope of the present disclosure.

The suffixes “module” and “unit” used herein are used only for distinguishment between constituent elements and, as such, should not be interpreted as representing that the constituent elements are physically and chemically distinguished or separated from each other or as suggesting that the constituent elements are distinguishable or separable from each other.

Although terms including ordinal numbers, such as such as “first”, “second”, etc., may be used to describe various constituent elements, the constituent elements are not limited to the terms. The terms may be used only as names for distinguishing one constituent element from another constituent element, and meaning of the order between the constituent elements may be identified through context of the description of the constituent elements in place of the names.

The term “and/or” is used to include a combination of any of a plurality of items associated therewith. For example, the phrase “A or B” will be understood to include three cases of “A”, “B” and “A and B” on the whole.

In the case where an element is described as being “connected” or “linked” to another element, it should be understood that the element may be directly connected or linked to the other element, or another element may be present therebetween.

It should be noted that terms used herein are merely used to describe a specific embodiment, not to limit the present disclosure. Incidentally, unless clearly used otherwise, singular expressions include a plural meaning. In this application, the term “comprising”, “including” or the like is intended to express the existence of the characteristic, the numeral, the step, the operation, the element, the part, or the combination thereof, and does not exclude another characteristic, numeral, step, operation, element, part, or any combination thereof, or any addition thereto.

Unless defined otherwise, terms used herein including technological or scientific terms have the same meaning as generally understood by those of ordinary skill in the art to which the disclosure pertains. The terms used herein shall be interpreted not only based on the definition of any dictionary but also the meaning that is used in the field to which the disclosure pertains. In addition, unless clearly defined, the terms used herein shall not be interpreted too ideally or formally.

In addition, the term “unit”, “control unit”, “control device” or “controller” is only a term widely used for designation of an appliance for controlling a function associated therewith and, as such, does not mean a generic functional unit. For example, the appliance may include a communication device configured to communicate with another controller or a sensor, for control of a function to be performed thereby, a recording medium that can be read by a computer and is configured to store an operating system, logic commands, input/output information, etc., and at least one processor configured to execute comparison, discrimination, calculation, determination, etc. required for control of the function to be performed.

Meanwhile, the processor may include a semiconductor integrated circuit and/or electronic elements configured to execute at least one or more of comparison, discrimination, calculation, and determination in order to achieve a programmed function. For example, the processor may be one or a combination of a computer, a microprocessor, a central processing unit (CPU), an application specific integrated circuit (ASIC), circuitry, and logic circuits.

The processor may be electrically connected to a memory. The processor may read out data from the memory and may write the read-out data. The memory and the processor may be integrated with each other or may be physically separated from each other.

Hereinafter, embodiments of the present disclosure will be described in detail with reference to the accompanying drawings.

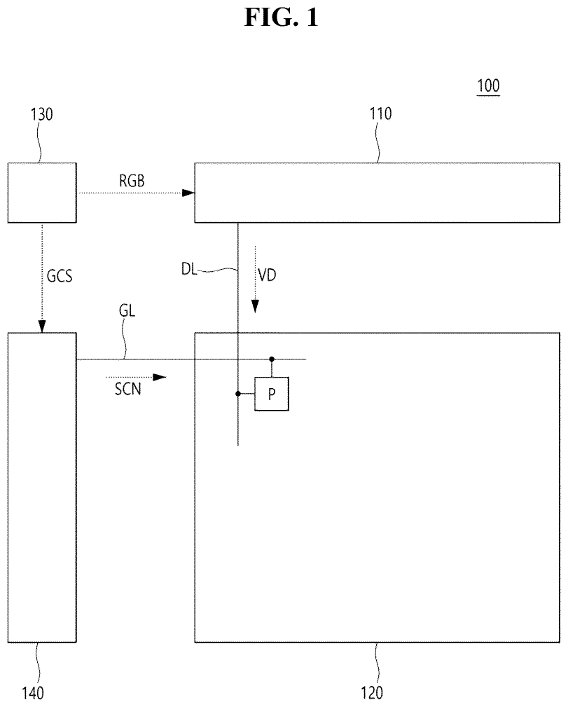

FIG. 1 is a diagram illustrating a configuration of a display device according to an embodiment of the present disclosure.

Referring to FIG. 1, a display driving device 100 may include a display panel 120, a timing controller 130, a gate driving device 140, a data driving device 110, etc.

The display panel 120 may be a liquid crystal display (LCD) panel or a self-luminous device panel such as an organic light emitting diode (OLED) panel.

When the display panel 120 is an LCD panel, the display panel 120 may include a backlight, liquid crystals, and a common electrode, and a pixel electrode and a driving transistor may be disposed at each pixel. When a scan signal is applied to the gate of the driving transistor, the driving transistor turns on and, as such, a data voltage may be supplied to the pixel electrode. Then, in accordance with the data voltage, an electric field is formed between the pixel electrode and the common electrode, changing the alignment direction of the liquid crystals. Accordingly, the transmittance of light supplied from the backlight is varied and, as such, the brightness of the pixel may be adjusted.

At the display panel 120, a plurality of data lines DL and a plurality of gate lines GL may be arranged in a matrix. Each data line DL may be connected to the source terminal of the driving transistor of each pixel corresponding thereto, and each gate line GL may be connected to the gate terminal of the driving transistor of each pixel corresponding thereto. When a scan signal SCN is supplied to the gate line GL, the driving transistor turns on, allowing a data voltage VD supplied through the data line DL to be transferred to the pixel electrode.

The display panel 120 may be a self-luminous device panel such as an OLED panel. In addition to the OLED panel, the self-luminous device panel may employ other types of self-luminous devices such as a micro-LED panel or the like.

At each pixel of an OLED panel, a scan transistor, a driving transistor, an OLED, etc. may be disposed. When a scan signal SCN is applied to the gate of the scan transistor, the scan transistor turns on, and the data voltage VD may be supplied to the driving transistor through the scan transistor. In the OLED panel, the data voltage VD may be supplied to the gate of the driving transistor. The magnitude of the data voltage VD determines the intensity of conduction current of the driving transistor, and the brightness of the OLED connected to the driving transistor may be adjusted in accordance with the intensity of the conduction current.

A parasitic capacitor may be formed on the data line DL. The parasitic capacitor may be formed between the data line DL and the cathode of the OLED or between the data line DL and the anode of the OLED. At the side of the data driving device 110 that supplies the data voltage VD, the parasitic capacitor may be recognized as a load. When the capacitance of the parasitic capacitor increases, the data driving device 110 should supply higher power to the data line DL.

The timing controller 130 may receive image data from an external device, for example, a device referred to as a host or an application processor (AP). The timing controller 130 may convert image data formatted for the external device into image data RGB in a format that may be processed by the data driving device 110. The timing controller 130 may then transmit the converted image data RGB to the data driving device 110.

The image data RGB may include pixel data indicating grayscale values for respective pixels P. The pixel data for one pixel P may be, for example, 8-bit data and may express a grayscale value selected from 0 to 255. The timing controller 130 may generate pixel data on a pixel basis and may transmit the pixel data to the data driving device 110 under the condition that the pixel data is included in the image data RGB.

The timing controller 130 may transmit control signals to devices associated with driving of the display panel, for example, the data driving device 110 and the gate driving device 140. The timing controller 130 may transmit a data control signal DCS to the data driving device 110 and may transmit a gate control signal GCS to the gate driving device.

The control signals DCS and GCS may include setting information for respective devices associated therewith. For example, the timing controller 130 may receive setting information from an external device, may identify the setting information for each device, and may then transmit the setting information under the condition that the setting information is included in the corresponding control signal DCS or GCS.

The control signals DCS and GCS may include timing signals for controlling respective devices. The timing signals may include, for example, a vertical synchronization signal Vsync, a horizontal synchronization signal Hsync, etc. In accordance with the timing signals, the data driving device 110 or the gate driving device 140 may distinguish frames and may distinguish horizontal periods.

The gate driving device 140 may supply a scan signal SCN to the pixels P disposed at the display panel 120. Pixels to which a scan signal SCN instructing turn-on is supplied are selected, and a data voltage VD may be supplied to the selected pixels.

The gate driving device 140 may supply the scan signal SCN via the gate lines GL. A plurality of gate lines GL may be disposed at the display panel 120. Each gate line GL may be connected to pixels P arranged in a line in one direction, for example, a horizontal direction. The gate driving device 140 may supply a scan signal SCN instructing turn-on to a selected one of the plurality of gate lines GL and, as such, the pixels P connected to the selected gate line GL may be selected. The gate driving device 140 may supply the scan signal SCN instructing turn-on in every horizontal period while changing the gate line GL to which the scan signal SCN is to be supplied.

The data driving device 110 may drive the pixels P disposed at the display panel 120.

The data driving device 110 may receive image data RGB from the timing controller 130. The data driving device 110 may then identify pixel data for each pixel P included in the image data RGB, may generate a data voltage VD corresponding to the pixel data, and may supply the data voltage VD to the pixel P.

The pixel data may represent a grayscale value for the pixel P, and the data driving device 110 may generate a data voltage VD corresponding to the grayscale value.

The pixel data may be stored in a latch circuit of the data driving device 110 and may then be output in the form of a digital signal. In addition, the data driving device 110 may convert the digital signal into an analog voltage using gamma reference voltages.

There is a difference between the grayscale corresponding to physical brightness and the grayscale corresponding to brightness perceived by a person. Correcting this difference is called gamma correction. Upon converting a digital signal to an analog voltage, the data driving device 110 may apply gamma correction simultaneously. For example, the data driving device 110 may apply digital-to-analog conversion and gamma correction at the same time, using voltages used for digital-to-analog conversion as voltages to which gamma correction is applied, that is, gamma reference voltages.

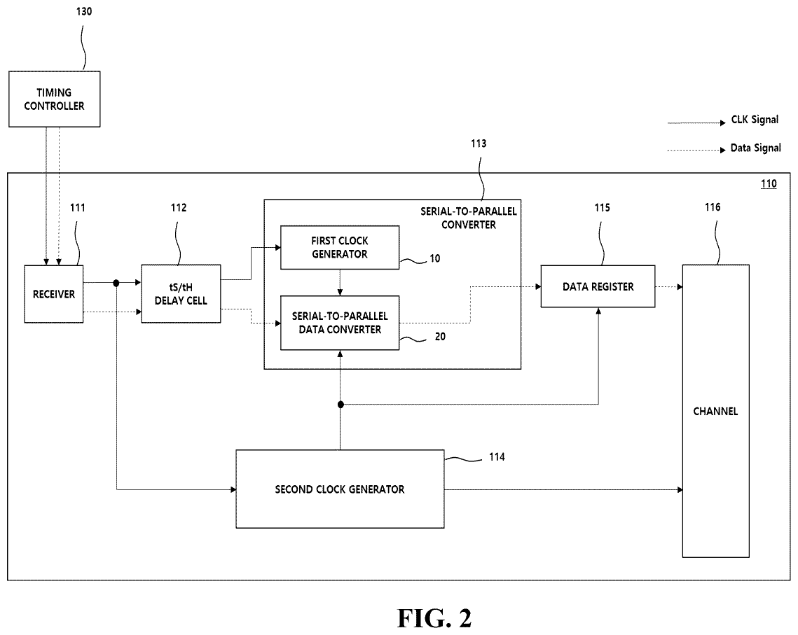

FIG. 2 is a diagram of a configuration of the data driving device according to an embodiment of the present disclosure.

Referring to FIG. 2, the data driving device 110 according to the embodiment of the present disclosure includes a receiver 111, a tS/tH delay cell 112, a serial-to-parallel converter 113, a second clock generator 114, a data register 115, and a channel 116.

Of course, the components shown in FIG. 2 represent only those relevant to the embodiment, and in actual implementations, additional components may be included in the data driving device 110.

The receiver 111 receives signals transmitted from the timing controller 130. In an example of the present disclosure, the transmitted signals may include a mini-LVDS signal.

The mini-LVDS signal is a low-voltage differential signal and includes data and clock information. The transmission voltage range of the mini-LVDS signal is generally low (e.g., about ±0.35 V), which reduces power consumption and minimizes signal interference, but the signal may be weak at the receiver 111. To this end, the receiver 111 may use voltage conversion and amplification circuits to convert the received signal to a voltage level usable by logic circuits. The receiver 111 may convert the differential mini-LVDS signal into a single signal or may amplify the voltage level of the converted signal to a level recognizable by digital logic circuits (e.g., 0.35 V→1.8 V or 3.3 V).

The receiver 111 may generally include a clock and data recovery (CDR). In accordance with an embodiment of the present disclosure, however, the receiver 111 may not in include the CDR. In the case in which the receiver 111 does not include the CDR, the timing controller 130 may transmit data and a clock signal separately. Here, the data signal is bit information required for the display pixels, and the clock signal may be a reference signal for data sampling and synchronization.

The tS/tH delay cell 112 is a component that ensures system stability by adjusting timing of the data signal and the clock signal received from the receiver 111. The tS/tH delay cell 112 may add a delay to the input data signal such that the input data signal satisfies setup time (tS) and hold time (tH) conditions. The setup time (tS) is the time during which the data must be stably prepared before a clock edge, and the hold time (tH) is the time during which the data must be stably maintained after the clock edge.

The tS/tH delay cell 112 may be implemented through various systems such as an RC delay circuit system configured to delay a signal in an analog manner using a resistor and a capacitor, a buffer chain system configured to delay a signal by multiple buffers connected in series, a programmable delay system which is a variable delay circuit controllable a delay time, etc.

The first clock generator 10 may be included in the serial-to-parallel converter 113. Based on the clock signal transmitted through the receiver 111 and the tS/tH delay cell 112, the first clock generator 10 generates a plurality of new clock signals. The newly generated plurality of clock signals is transferred to the serial-to-parallel data converter 20 so as to be used for data sampling in a procedure of converting serial data into parallel data. In the present disclosure, the parallel data converted based on clocks generated in the first clock generator 10 is referred to as first and second parallel data.

The second clock generator 114 generates a plurality of new clock signals based on the clock signal received from the receiver 111. The newly generated plurality of clock signals is transferred to the serial-to-parallel data converter 20 and is used to sample the first and second parallel data converted in the serial-to-parallel data converter 20 based on the clock signals generated by the first clock generator 10. In the present disclosure, the parallel data converted based on clocks generated by the second clock generator 114 is referred to as third and fourth parallel data.

The second clock generator 114 may transmit clock signals not only to the serial-to-parallel data converter 20, but also to the data register 115 and each channel 116. Of course, in actual implementations, the second clock generator 114 may also transmit clock signals to a plurality of logic circuits that require the clock signals. Each channel 116 may include a latch circuit, a digital-to-analog converter, an output buffer, etc.

The serial-to-parallel data converter 20 may be included in the serial-to-parallel converter 113. When a plurality of clock signals generated in the first clock generator 10 is input to the serial-to-parallel data converter 20, the plurality of clock signals is synchronized with bits of a serial data signal input to the serial-to-parallel data converter 20 such that bit data is sampled at rising or falling edges of clocks. Thus, the serial data signal may be converted into parallel data. In the present disclosure, the converted parallel data is referred to as first and second parallel data. The first and second parallel data are sampled based on clocks generated in the second clock generator 114 to generate additional parallel data. In the present disclosure, the additional parallel data is referred to as third and fourth parallel data. The serial-to-parallel data converter 20 may transmit the third and fourth parallel data to the data register 115.

Here, parallel data may be formed through various methods such as a method in which each parallel data line receives a new data bit whenever new serial data is received, a method in which specific data is copied across a plurality of parallel data lines such that the specific data is replicated to enable execution of multi-processing or to enable simultaneous use of the same data on a plurality of output lines, a method in which, when a plurality of independent serial data streams is input, each stream forms a parallel data line, etc. In an embodiment of the present disclosure, the method of forming parallel data may be a method in which each parallel data line receives a new data bit whenever new serial data is received. This method may be a method in which input serial data is continuously received, and new parallel data is continuously generated in accordance with clock signals.

The data register 115 stores the parallel data (third and fourth parallel data) received from the serial-to-parallel data converter 20 and maintains the parallel data (third and fourth parallel data) in a stable state for subsequent processing. Here, the method of storing the parallel data in the data register may include a method of storing all data of one frame in the data register or a method of storing selected data among multiple data of one frame in the data register. In accordance with an embodiment of the present disclosure, since the serial-to-parallel data converter 20 converts all pixel data of one frame into parallel data for subsequent processing thereof, the data register 115, which receives the converted parallel data, may store all data of one frame. However, the present disclosure is not limited to the above-described method.

The data register 115 may operate based on a clock signal synchronized upon being output from the serial-to-parallel converter 113 and may transmit data stored therein to each channel 116. Each channel 116 may include a latch circuit, a digital-to-analog converter, an output buffer, etc.

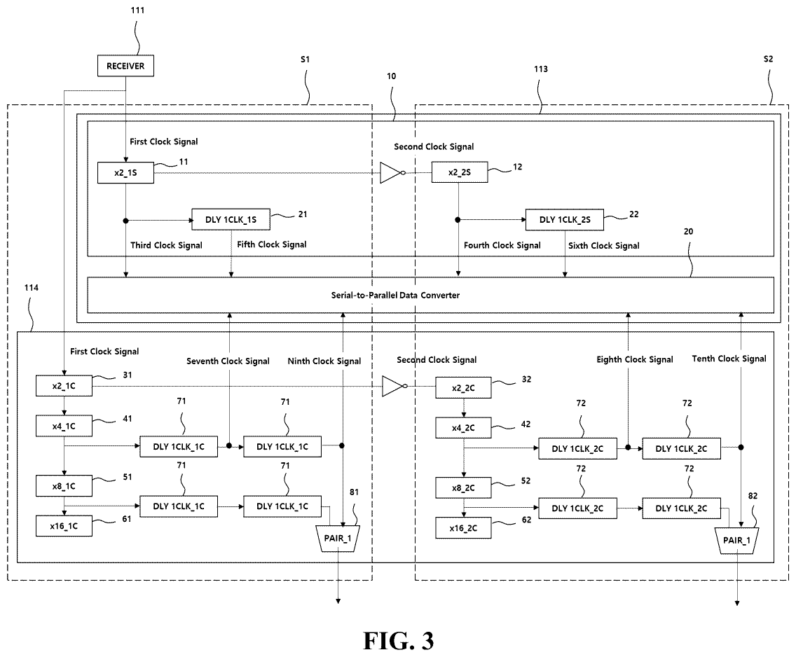

FIG. 3 is a diagram illustrating operation of the serial-to-parallel converter and the second clock generator according to an embodiment of the present disclosure.

Referring to FIG. 3, the data driving device 110 includes the serial-to-parallel converter 113 and the second clock generator 114, and the serial-to-parallel converter 113 includes the first clock generator 10 and the serial-to-parallel data converter 20.

Additionally, the serial-to-parallel converter 113 and the second clock generator 114 may be configured to operate through first data transmission step S1 and second data transmission step S2 divided from each other. Here, first data is data of odd-numbered bits of a data signal transferred from the receiver 111, and second data is data of even-numbered bits of the data signal transferred from the receiver 111. First and second data, which are serial data, are converted into parallel data in the serial-to-parallel converter 113 and may then be transferred to the data register 115.

The first data transmission step S1 may operate based on a first clock signal CLK, and the second data transmission step S2 may operate based on a second clock signal CLKB.

In operation of the first data transmission step S1, the first clock generator 10 includes an x2_1S 11 and a DLY 1CLK_1S 21.

In operation of the first data transmission step S1, the receiver 111 transfers the first clock signal to the first clock generator 10. Although not shown in FIG. 1, the tS/tH delay cell 112 is present between the receiver 111 and the first clock generator 10 to adjust timing of data and clock signals received from the receiver 111.

In operation of the first data transmission step S1, the x2_1S 11 of the first clock generator 10 receives the first clock signal from the receiver 111 and generates a third clock signal having a period corresponding to two times the period of the first clock signal.

In operation of the first data transmission step S1, the DLY 1CLK_1S 21 of the first clock generator 10, which is a delay circuit, delays the third clock signal received from the x2_1S 11 by a 1-CLK time to generate a fifth clock signal. Here, the 1-CLK time is based on a basic clock signal transferred from the receiver 111, i.e., the first clock signal.

In operation of the first data transmission step S1, the third clock signal output from the x2_1S 11 of the first clock generator 10 and the fifth clock signal output from the DLY 1CLK_1S 21 are input to the serial-to-parallel data converter 20, and are synchronized with a data signal input to the serial-to-parallel data converter 20 such that data is sampled at rising or falling edges of clocks. Thus, the data signal may be converted into a parallel data format. In the present disclosure, the parallel data converted based on clocks generated in the first clock generator 10 in the first data transmission step S1 is referred to as “first parallel data”.

In the related art, since there is no process of generating a clock signal having an increased period based on the clock signal transmitted from the receiver or delaying the generated clock signal to generate another signal, data must be sampled by mixing the clock signal and the inverted-phase clock signal. This leads to an insufficient timing margin, making application to high-frequency products difficult. However, in the present disclosure, the third clock signal is generated to have a period corresponding to two times the period of the first clock signal, and the third clock signal is delayed to generate the fifth clock signal. Based on the third and fifth clock signals, the serial-to-parallel converter 113 samples serial data and converts the sampled serial data into parallel data (referred to in the present disclosure as first parallel data), thereby doubling the timing margin during sampling, as compared to conventional cases. Accordingly, frequency characteristics may be enhanced.

The receiver 111 may transfer the first clock signal to the second clock generator 114.

In operation of the first data transmission step S1, the second clock generator 114 includes an x2_1C 31, an x4_1C 41, an x8_1C 51, an x16_1C 61, a DLY 1CLK_1C 71, and a PAIR_1 81.

In operation of the first data transmission step S1, the x2_1C 31, the x4_1C 41, the x8_1C 51, and the x16_1C 61 of the second clock generator 114 are clock period multipliers configured to increase the period of the first clock signal transferred from the receiver 111. The x2_1C 31, the x4_1C 41, the x8_1C 51, and the x16_1C 61 may increase the clock period 2 times, 4 times, 8 times, and 16 times, respectively. Each clock period multiplier may be selected and activated in accordance with the data sampling method of the serial-to-parallel data converter 20. Data sampling of the serial-to-parallel data converter 20 according to an embodiment of the present disclosure is executed based on the x4_1C 41 as an example.

In operation of the first data transmission step S1, the x4_1C 41 of the second clock generator 114, which is a circuit configured to increase the clock period four times, may increase the period of the first clock signal four times. After increasing the first clock signal four times, the second clock generator 114 delays the first clock signal by a 1-CLK time in the delay circuit DLY 1CLK_1C 71 to generate a seventh clock signal. Then, the second clock generator 114 delays the seventh clock signal by a 1-CLK time in the DLY 1CLK_1C 71, which is a delay circuit, to generate a ninth clock signal.

In operation of the first data transmission step S1, the seventh and ninth clock signals are input to the serial-to-parallel data converter 20. In the serial-to-parallel data converter 20, the seventh and ninth clock signals may be used to sample the first parallel data at rising or falling clock edges and to convert the sampled data into third parallel data. The serial-to-parallel data converter 20 may transmit the third parallel data to the data register 115.

In this case, the seventh clock signal and the ninth clock signal may sample the first parallel data under the condition that there is a delay of a 1-CLK time between the seventh clock signal and the ninth clock signal. In the related art, two clock signals used to sample parallel data have a 0.5 CLK delay, resulting in an insufficient timing margin. As a result, there is a difficulty in supporting high frequencies. In the present disclosure, however, the seventh and ninth clock signals sample the first parallel data under the condition that there is a delay of a 1-CLK time between the seventh clock signal and the ninth clock signal and, as such, the timing margin may be doubled, thereby enhancing frequency characteristics.

The PAIR_1 81 may be a component configured to select clocks with different periods generated in the second clock generator 114 based on the first clock signal and to transfer the selected clocks to other logic circuits requiring clock signals such as the channel 116 or the like. For example, the PAIR_1 81 may be configured to select one of values High and Low. Here, the value High corresponds to 6PAIR and the value Low corresponds to 3PAIR. When the PAIR_1 81 selects the value High, 6-line data may be transferred in synchronization with the clock signal of the x4_1C 41, whereas, when the PAIR_1 81 selects the value Low, 3-line data may be transferred in synchronization with the clock signal of the x8_1C 51. This is merely an example and may, of course, be modified to suit user environments.

In operation of the second data transmission step S2, the first clock generator 10 includes an x2_2S 12 and a DLY 1CLK_2S 22.

In operation of the second data transmission step S2, the x2_2S 12 of the first clock generator 10 receives the second clock signal, which is obtained by 180° phase-shifting the first clock signal transferred from the receiver 111, and generates a fourth clock signal having a period corresponding to two times the period of the second clock signal.

In operation of the second data transmission step S2, the DLY 1CLK_2S 22 of the first clock generator 10, which is a delay circuit, may generate a sixth clock signal by delaying the fourth clock signal received from the x2_2S 12 by an 1-CLK time. Here, the 1-CLK time is based on a basic clock signal transferred from the receiver 111, i.e., the first clock signal.

In operation of the second data transmission step S2, the fourth clock signal output from the x2_2S 12 of the first clock generator 10 and the sixth clock signal output from the DLY 1CLK_2S 22 are input to the serial-to-parallel data converter 20, and are synchronized with the data signal input to the serial-to-parallel data converter 20 such that data is sampled at rising or falling edges of clocks. Thus, the data signal is converted into a parallel data format. In the present disclosure, the parallel data converted based on clocks generated in the first clock generator 10 in the second data transmission step S2 is referred to as “second parallel data.”

In the related art, since there is no process of generating a clock signal having an increased period based on the clock signal transmitted from the receiver or delaying the generated clock signal to generate another signal, data must be sampled by mixing the clock signal and the inverted-phase clock signal. This leads to an insufficient timing margin, making application to high-frequency products difficult. However, in the present disclosure, the fourth clock signal is generated to have a period corresponding to two times the period of the second clock signal, and the fourth clock signal is delayed to generate the sixth clock signal. Based on the fourth and sixth clock signals, the serial-to-parallel converter 113 samples serial data and converts the sampled serial data into parallel data (referred to in the present disclosure as second parallel data), thereby doubling the timing margin during sampling, as compared to conventional cases. Accordingly, frequency characteristics may be enhanced.

The receiver 111 may transfer the first clock signal to the second clock generator 114.

In operation of the second data transmission step S2, the second clock generator 114 includes an x2_2C 32, an x4_2C 42, an x8_2C 52, an x16_2C 62, a DLY 1CLK_2C 72, and a PAIR_2 82.

In operation of the second data transmission step S2, the x2_2C 32, the x4_2C 42, the x8_2C 52, and the x16_2C 62 of the second clock generator 114 are clock generators configured to generate clock signals having periods corresponding to two times, four times, eight times, and sixteen times the period of the second clock signal, respectively. The second clock signal is obtained by 180° phase-shifting the first clock signal transferred from the receiver 111. The x2_2C 32, the x4_2C 42, the x8_2C 52, and the x16_2C 62 may increase the clock period 2 times, 4 times, 8 times, and 16 times, respectively. Each clock period multiplier may be selected and activated in accordance with the data sampling method of the serial-to-parallel data converter 20. Data sampling of the serial-to-parallel data converter 20 according to an embodiment of the present disclosure is executed based on the x4_2C 42 as an example.

In operation of the second data transmission step S2, the x4_2C 42 of the second clock generator 114, which is a circuit configured to increase the clock period 4 times, may increase the second clock signal four times. After increasing the first clock signal four times, the second clock generator 114 delays the first clock signal by a 1-CLK time in the DLY 1CLK_2C 72, which is a delay circuit, to generate an eighth clock signal. Then, the second clock generator 114 delays the eighth clock signal by a 1-CLK time in the delay circuit DLY 1CLK_2C 72 to generate a tenth clock signal.

The eighth and tenth clock signals are input to the serial-to-parallel data converter 20 to be used to sample the second parallel data on rising or falling edges of clocks and to convert the sampled data into fourth parallel data. The serial-to-parallel data converter 20 may output the fourth parallel data to the data register 115.

In this case, the eighth and tenth clock signals may sample the second parallel data under the condition that there is a delay of a 1-CLK time between the eighth clock signal and the tenth clock signal. In the related art, two clock signals used to sample parallel data have a 0.5 CLK delay, resulting in an insufficient timing margin. As a result, there is a difficulty in supporting high frequencies. In the present disclosure, however, the eighth and tenth clock signals may sample the second parallel data under the condition that there is a delay of a 1-CLK time between the eighth clock signal and the tenth clock signal and, as such, the timing margin may be doubled, thereby enhancing frequency characteristics.

The PAIR_2 82 may be a component configured to select clocks with different periods generated in the second clock generator 114 based on the second clock signal and to transfer the selected clocks to other logic circuits requiring clock signals such as the channel 116 or the like. For example, the PAIR_2 82 may be configured to select one of values High and Low. Here, the value High corresponds to 6PAIR and the value Low corresponds to 3PAIR. When the PAIR_2 82 selects the value High, 6-line data may be transferred in synchronization with the clock signal of the x4_2C 42, whereas, when the PAIR_2 82 selects the value Low, 3-line data may be transferred in synchronization with the clock signal of the x8_2C 52. This is merely an example and may, of course, be modified to suit user environments.

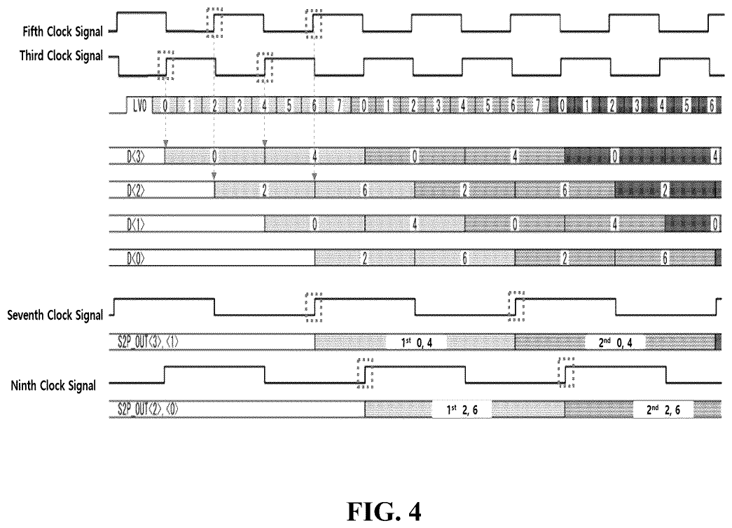

FIG. 4 is a diagram of clock signals and data sampling timing in the serial-to-parallel converter in the first data transmission step according to an embodiment of the present disclosure.

Referring to FIG. 4, the third, fifth, seventh, and ninth clock signals in the first data transmission step S1 are shown.

The third clock signal in the first data transmission step S1 is generated in the first clock generator 10 and has a period corresponding to two times the period of the first clock signal transferred from the receiver 111. The serial-to-parallel data converter 20 synchronizes the third clock signal with a first bit (0) and a fifth bit (4) among LV0 data bits, and stores the first bit (0) and the fifth bit (4) in parallel in data streams D<3> and D<1> through sampling. Here, synchronization between the third clock signal and the LV0 data bits may occur at rising edges of the clock signal.

The fifth clock signal in the first data transmission step S1 is generated in the first clock generator 10 and is a signal delayed by a 1-CLK time from the third clock signal. Here, the 1-CLK time is based on the basic clock signal transferred from the receiver 111, i.e., the first clock signal. The serial-to-parallel data converter 20 synchronizes the fifth clock signal with a third bit (2) and a seventh bit (6) among the LV0 data bits, and stores the third bit (2) and the seventh bit (6) in parallel in data streams D<2> and D<0> through sampling. Synchronization between the fifth clock signal and the LV0 data bits may occur at rising edges of the clock signal. In the present disclosure, signals of the parallel data D<3>, D<2>, D<1>, and D<0> generated based on the third and fifth clock signals are referred to as “first parallel data”.

The seventh clock signal in the first data transmission step S1 is generated in the second clock generator 114. The seventh clock signal is a signal having a period corresponding to four times the period of the first clock signal transferred from the receiver 111 and delayed by the 1-CLK time from the first clock signal. The serial-to-parallel data converter 20 synchronizes the seventh clock signal with bit information stored in the data streams D<3> and D<1> of the first parallel data, samples the first bit (0) and the fifth bit (4) stored in the data streams D<3> and D<1> of the first parallel data, stores the sampled first bit (0) and fifth bit (4) in a data stream S2P_OUT<3>, <1>, and then sequentially outputs the first bit (0) and the fifth bit (4) to the data register 115 (first, 0 and 4, second, 0 and 4, third, 0 and 4, ...). Here, synchronization between the seventh clock signal and the data streams D<3> and D<1> may occur at rising edges of the clock signal.

The ninth clock signal in the first data transmission step S1 is a signal delayed by 1-CLK from the seventh clock signal. The serial-to-parallel data converter 20 synchronizes the ninth clock signal with bit information stored in the data streams D<2> and D<0>, samples the third bit (2) and the seventh bit (6) stored in the data streams D<2> and D<0> of the first parallel data, stores the sampled third bit (2) and seventh bit (6) in a data stream S2P_OUT<2>, <0>, and then sequentially outputs the third bit (2) and the seventh bit (6) to the data register 115 (first, 2 and 6, second, 2 and 6, third, 2 and 6, ...). Synchronization between the ninth clock signal and the data streams D<2> and D<0> may occur at rising edges of the clock signal. In the present disclosure, the parallel data stream S2P_OUT<3>, <1> and the parallel data stream S2P_OUT<2>, <0> generated based on the seventh and ninth clock signals are referred to as “third parallel data”.

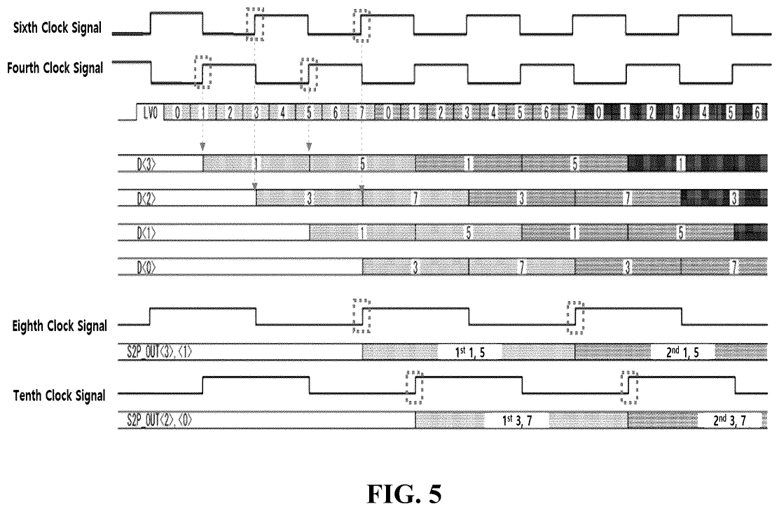

FIG. 5 is a diagram of clock signals and data sampling timing in the serial-to-parallel converter in the second data transmission step according to an embodiment of the present disclosure.

Referring to FIG. 5, the fourth, sixth, eighth, and tenth clock signals in the second data transmission step S2 are shown.

The fourth clock signal in the second data transmission step S2 is generated in the first clock generator 10 and has a period corresponding to two times the period of the second clock signal, which is obtained by 180°phase-shifting the first clock signal transferred from the receiver 111. The serial-to-parallel data converter 20 synchronizes the fourth clock signal with a second bit (1) and a sixth bit (5) among the LV0 data bits, and stores the second bit (1) and the sixth bit (5) in parallel in the data streams D<3> and D<1> through sampling. Synchronization between the fourth clock signal and the LV0 data bits may occur at rising edges of the clock signal.

The sixth clock signal in the second data transmission step S2 is generated in the first clock generator 10 and is a signal delayed by a 1-CLK time from the fourth clock signal. Here, the 1-CLK time is based on the basic clock signal transferred from the receiver 111, i.e., the first clock signal. The serial-to-parallel data converter 20 synchronizes the sixth clock signal with a fourth bit (3) and an eighth bit (7) among the LV0 data bits, and stores the fourth bit (3) and the eighth bit (7) in parallel in the data streams D<2> and D<0> through sampling. Synchronization between the sixth clock signal and the LV0 data bits may occur at rising edges of the clock signal. In the present disclosure, signals of the parallel data stream D<3>, D<2>, D<1>, and D<0> generated based on the fourth and sixth clock signals are referred to as “second parallel data”.

The eighth clock signal in the second data transmission step S2 is generated in the second clock generator 114. The eighth clock signal has a period corresponding to four times the period of the second clock signal, which is obtained by 180°phase-shifting the first clock signal transferred from the receiver 111, and is delayed by the 1-CLK time from the second clock signal. The serial-to-parallel data converter 20 synchronizes the eighth clock signal with bit information stored in the data streams D<3> and D<1>, samples the second bit (1) and the sixth bit (5) stored in the data streams D<3> and D<1> of the second parallel data, stores the sampled second bit (1) and sixth bit (5) in the data stream S2P_OUT<3>, <1>, and then sequentially outputs the second bit (1) and the sixth bit (5) to the data register 115 (first, 1 and 5, second, 1 and 5, third, 1 and 5, ...). Synchronization between the eighth clock signal and the data streams D<3> and D<1> may occur at rising edges of the clock signal.

The tenth clock signal in the second data transmission step S2 is a signal delayed by the 1-CLK time from the seventh clock signal. The serial-to-parallel data converter 20 synchronizes the ninth clock signal with the bit information stored in the data streams D<2> and D<0>, samples the fourth bit (3) and the eighth bit (7) stored in the data streams D<2> and D<0> of the first parallel data, stores the sampled fourth bit (3) and eighth bit (7) in the data stream S2P_OUT<2>, <0>, and then sequentially outputs the fourth bit (3) and the eighth bit (7) to the data register 115 (first, 3 and 7, second, 3 and 7, third, 3 and 7, ...). Synchronization between the tenth clock signal and the data streams D<2> and D<0> may occur at rising edges of the clock signal. In the present disclosure, the parallel data stream S2P_OUT<3>, <1> and the parallel data stream S2P_OUT<2>, <0> generated based on the eighth and tenth clock signals are referred to as “fourth parallel data”.

It will be apparent to those skilled in the art that the present disclosure may be embodied in other specific forms without departing from the spirit and essential characteristics of the disclosure. Therefore, the above detailed description should not be construed as limiting in any respect but rather as illustrative. The scope of the disclosure should be determined by the reasonable interpretation of the appended claims, and all modifications within the equivalent scope of the disclosure are included within the scope of the disclosure.

The method according to the above-described embodiments may be composed as a program to be executed by a computer, and may be stored in a recording medium that can be read by a computer. Examples of the recording medium that may be read by a computer may include a read only memory (ROM), a random access memory (RAM), a CD-ROM, a magnetic tape, a floppy disk, an optical data storage, etc. and also include implementations in the form of a carrier wave (e.g., transmission over the Internet).

The computer-readable recording medium is distributed to computer systems connected over a network, and computer-readable code may be stored and executed in a distributed manner. Furthermore, a functional program, code, and code segments for implementing the above-described method may be easily inferred by programmers in the technical field to which the embodiment pertains.

As apparent from the above description, in accordance with at least one embodiment of the present disclosure, it may be possible to enhance a timing margin by separating operation steps of a clock signal (CLK) and an inverted-phase clock signal (CLKB) during data processing. Accordingly, stable operation may be achieved without signal interference even in high-speed data transmission environments.

Effects attainable through the present disclosure are not limited to the above-described effects, and other effects of the present disclosure not described herein will be more clearly understood by those skilled in the art from the above description.

It will be apparent to those skilled in the art that the present disclosure may be embodied in various specific forms without departing from the spirit and essential characteristics of the disclosure.

Accordingly, the above detailed description should not be construed as limiting in any respect but rather as illustrative. The scope of the disclosure should be determined by the reasonable interpretation of the appended claims, and all modifications within the equivalent scope of the disclosure are included within the scope of the disclosure.

What is claimed is:

1. A driving method of a data driving device comprising:
receiving a data signal and a first clock signal from a timing controller;
generating a second clock signal having a phase difference of 180° based on the received first clock signal; and
transmitting first data, which are some bit data of the data signal, to a data register based on the first clock signal, and transmitting second data, which are remaining bit data of the data signal, to the data register based on the second clock signal.

2. The driving method according to claim 1, wherein the some bit data are odd-numbered bits of the data signal, and the remaining bit data are even-numbered bits of the data signal.

3. The driving method according to claim 1, wherein the transmitting the first data to the data register based on the first clock signal comprises:
generating a third clock signal having a period corresponding to two times a period of the first clock signal; and
generating a fifth clock signal delayed from the third clock signal by a 1-CLK time,
wherein the 1-CLK time is based on the first clock signal.

4. The driving method according to claim 3, wherein transmitting the first data to the data register based on the first clock signal further comprises:
sampling the first data at rising edges of the third clock signal and the fifth clock signal to generate first parallel data.

5. The driving method according to claim 4, wherein the transmitting the first data to the data register based on the first clock signal further comprises:
generating a seventh clock signal having a period corresponding to four times the period of the first clock signal and delayed from the first clock signal by the 1-CLK time; and
generating a ninth clock signal delayed from the seventh clock signal by the 1-CLK time.

6. The driving method according to claim 5, wherein the transmitting the first data to the data register based on the first clock signal further comprises:
sampling the first parallel data at rising edges of the seventh clock signal and the ninth clock signal to generate third parallel data; and
transmitting the third parallel data to the data register.

7. The driving method according to claim 1, wherein the transmitting the second data to the data register based on the second clock signal comprises:
generating a fourth clock signal having a period corresponding to two times a period of the second clock signal; and
generating a sixth clock signal delayed from the fourth clock signal by a 1-CLK time; and
the 1-CLK time is based on the first clock signal.

8. The driving method according to claim 7, wherein the transmitting the second data to the data register based on the second clock signal further comprises:
sampling the second data at rising edges of the fourth clock signal and the sixth clock signal to generate second parallel data.

9. The driving method according to claim 8, wherein the transmitting the second data to the data register based on the second clock signal further comprises:
generating an eighth clock signal having a period corresponding to four times the period of the second clock signal and delayed from the second clock signal by the 1-CLK time; and
generating a tenth clock signal delayed from the eighth clock signal by the 1-CLK time.

10. The driving method according to claim 9, wherein the transmitting the second data to the data register based on the second clock signal further comprises:
sampling the second parallel data at rising edges of the eighth clock signal and the tenth clock signal to generate fourth parallel data; and
transmitting the fourth parallel data to the data register.

11. A data driving device comprising:
a receiver configured to receive a data signal and a first clock signal from a timing controller;
a first clock generator configured to generate a second clock signal having a phase difference of 180°based on the received first clock signal; and
a serial-to-parallel conversion unit configured to transmit first data, which are some bit data of the data signal, to a data register based on the first clock signal, and to transmit second data, which are remaining bit data of the data signal, to the data register based on the second clock signal.

12. The data driving device according to claim 11, wherein the some bit data are odd-numbered bits of the data signal, and the remaining bit data are even-numbered bits of the data signal.

13. The data driving device according to claim 11, wherein the first clock generator is configured to:
generate a third clock signal having a period corresponding to two times a period of the first clock signal; and
generate a fifth clock signal delayed from the third clock signal by a 1-CLK time,
wherein the 1-CLK time is based on the first clock signal.

14. The data driving device according to claim 13, wherein the first clock generator is configured to:
sample the first data at rising edges of the third clock signal and the fifth clock signal to generate first parallel data.

15. The data driving device according to claim 14, wherein the first clock generator is further configured to:
generate a seventh clock signal having a period that is four times a period of the first clock signal and delayed by the 1-CLK time; and
generate a ninth clock signal delayed from the seventh clock signal by the 1-CLK time.

16. The data driving device according to claim 15, wherein the first clock generator is further configured to:
sample the first parallel data at rising edges of the seventh clock signal and the ninth clock signal to generate third parallel data; and
transmit the third parallel data to the data register.

17. The data driving device according to claim 10, wherein the first clock generator is configured to:
generate a fourth clock signal having a period that is twice a period of the second clock signal; and
generate a sixth clock signal delayed from the fourth clock signal by a 1-CLK time,
wherein the 1-CLK time is based on the first clock signal.

18. The data driving device according to claim 17, wherein the first clock generator is further configured to:
sample the second data at rising edges of the fourth clock signal and the sixth clock signal to generate second parallel data.

19. The data driving device according to claim 18, wherein the first clock generator is further configured to:
generate an eighth clock signal having a period that is four times a period of the second clock signal and delayed by the 1-CLK time; and
generate a tenth clock signal delayed from the eighth clock signal by the 1-CLK time.

20. The data driving device according to claim 19, wherein the first clock generator is further configured to:
sample the second parallel data at rising edges of the eighth clock signal and the tenth clock signal to generate fourth parallel data; and
transmit the fourth parallel data to the data register.
